(19) United States
(12) Patent Application Publication
(10) Pub. No.: US 2025/0294677 A1
(43) Pub. Date: Sep. 18, 2025

(54) RESIN MULTILAYER SUBSTRATE AND ELECTRONIC DEVICE

(71) Applicant: Murata Manufacturing Co., Ltd., Nagaokakyo-shi (JP)

(72) Inventors: Akinori TAKEZAWA, Nagaokakyo-shi (JP); Masaki KAWATA, Nagaokakyo-shi (JP); Satoshi HORI, Nagaokakyo-shi (JP); Kousuke IKEUCHI, Nagaokakyo-shi (JP); Tomonori TACHINAMI, Nagaokakyo-shi (JP); Takayoshi YOSHIKAWA, Nagaokakyo-shi (JP); Daigo MATSUBARA, Nagaokakyo-shi (JP)

(73) Assignee: Murata Manufacturing Co., Ltd., Nagaokakyo-shi (JP)

(21) Appl. No.: 19/044,752

(22) Filed: Feb. 4, 2025

(30) Foreign Application Priority Data
Mar. 13, 2024 (JP) 2024-038639

(51) Int. Cl. H05K 1/03; H05K 1/02

(52) U.S. Cl. CPC H05K 1/036; H05K 1/0298

(57) ABSTRACT

A resin multilayer substrate having a resin multilayer body that has a first region, a second region, and a third region, as layer-direction regions. The resin multilayer substrate includes a first resin member affixed from the surface of the first region to the third region and a second resin member formed within the third region. The second resin member covers a portion of the first resin member, covering the end portion of the first resin member positioned in the third region. Assuming the Young's modulus of the first resin member is expressed as E1 and the Young's modulus of the second resin member by E2, E1<E2. Assuming the adhesion strength between the first resin member and the resin multilayer body is expressed as AD1, and the adhesion strength between the second resin member and the resin multilayer body as AD2, AD2≥AD1.

### CROSS-REFERENCE TO RELATED APPLICATION

This application claims priority to Japanese Patent Application No. JP 2024-038639 filed on Mar. 13, 2024. The entire contents of the above-identified applications, including the specifications, drawings and claims, are incorporated herein by reference in their entirety.

### BACKGROUND OF THE DISCLOSURE

### 1. Field of the Disclosure

The present disclosure relates to a resin multilayer substrate including a resin multilayer body composed of a stack of multiple resin layers, some of which include conductor patterns, and to electronic devices including the resin multilayer substrate.

### 2. Description of the Related Art

Japanese Unexamined Patent Application Publication No. 2019-16743 describes a multilayer substrate that has a first region and a second region. The first region differs from the second region with respect to thicknesses in the stacking direction, because the number of resin layers stacked in the first region differs from the number of resin layers stacked in the second region.

Assuming the number of stacked resin layers differs between the first region and the second region, a step is formed at the boundary between the first region and the second region.

### SUMMARY OF THE DISCLOSURE

Resin multilayer substrates including a resin multilayer body composed of a stack of multiple resin layers, some of which include conductor patterns, can have regions with different thicknesses in the stacking direction due to the positional relationship between conductor patterns or the specific usage of conductor patterns.

In another respect, to protect the circuits formed on a resin multilayer substrate or to reinforce the resin multilayer substrate, a non-conductive protective film can be affixed to the surface of the resin multilayer substrate with an interposed adhesive layer to cover the surface of the resin multilayer body.

However, assuming a resin multilayer body has large steps in thickness, it becomes challenging to form a continuous protective film over the steps. As a result, coverage by a continuous protective film is limited to regions with relatively even thicknesses. Assuming the resin multilayer substrate is formed in this manner, the end portion of the protective film is positioned within the inner portion of the resin multilayer substrate, rather than at the outer edge of the resin multilayer substrate. This positioning increases the likelihood of the protective film peeling off.

An object of the present disclosure is to provide a resin multilayer substrate in which the likelihood of a protective film, which protects the surface of a resin multilayer body, peeling off is reduced, and to provide electronic devices including the resin multilayer substrate.

(a) A resin multilayer substrate according to an embodiment of the present disclosure includes: a resin multilayer body composed of a stack of a plurality of resin layers, at least one of the resin layers including a conductor pattern, the resin multilayer body having a first region, a second region, and a third region between the first region and the second regions as layer-direction regions, assuming the average thickness of the first region of the resin multilayer body is expressed as T1, the average thickness of the second region of the resin multilayer body as T2, and the average thickness of the third region of the resin multilayer body as T3, these thicknesses are in the relationship T3<T1<T2; a first resin member covering an area from a surface of the first region to the third region; and a second resin member formed within the third region. The second resin member covers a portion of the first resin member, covering an end portion of the first resin member positioned in the third region. Assuming a Young's modulus of the first resin member is expressed as E1 and a Young's modulus of the second resin member as E2, E1<E2. Assuming an adhesion strength between the first resin member and the resin multilayer body is expressed as AD1 and an adhesion strength between the second resin member and the resin multilayer body as AD2, AD2≥AD1.

(b) An electronic device according to an embodiment of the present disclosure includes the resin multilayer substrate; and an electronic component mounted at the resin multilayer substrate, or an additional substrate having the resin multilayer substrate.

(c) An electronic device according to an embodiment of the present disclosure includes the resin multilayer substrate; and a casing enclosing the resin multilayer substrate.

The present disclosure provides a resin multilayer substrate in which the likelihood of a protective film, which protects the surface of a resin multilayer body, peeling off is reduced, and to provide electronic devices including the resin multilayer substrate.

### BRIEF DESCRIPTION OF THE DRAWINGS

FIG. 1 is a sectional view of a resin multilayer substrate 101A according to a first embodiment;

FIG. 2 is a partial plan view of the resin multilayer substrate 101A according to the first embodiment;

FIG. 3 is a sectional view of a resin multilayer substrate 101B according to a first embodiment;

FIG. 4 is a sectional view of a resin multilayer substrate 102 according to a second embodiment;

FIG. 5 is a sectional view of a resin multilayer substrate 103A according to a third embodiment;

FIG. 6 is a sectional view of a resin multilayer substrate 103B according to the third embodiment;

FIG. 7 is a sectional view of a resin multilayer substrate 104A according to a fourth embodiment;

FIG. 8 is a sectional view of a resin multilayer substrate 104B according to the fourth embodiment;

FIG. 9 is a sectional view of a resin multilayer substrate 104C according to the fourth embodiment;

FIG. 10 is a sectional view of a resin multilayer substrate 105 according to a fifth embodiment;

FIG. 11 is a sectional view of a resin multilayer substrate 106A according to a sixth embodiment;

FIG. 12 is a sectional view of a resin multilayer substrate 106B according to the sixth embodiment;

FIG. 13 is a sectional view of a resin multilayer substrate 106C according to the sixth embodiment;

FIG. 14 is a sectional view of a resin multilayer substrate 107 according to a seventh embodiment;

FIG. 15 is a sectional view of a resin multilayer substrate 108 according to an eighth embodiment;

FIG. 16 is a sectional view of a resin multilayer substrate 109 according to a ninth embodiment;

FIG. 17 is a sectional view of a resin multilayer substrate 110 according to a tenth embodiment;

FIG. 18 is a sectional view of a resin multilayer substrate 111 according to an eleventh embodiment;

The upper part of FIG. 19 provides a sectional view of a resin multilayer substrate 112 according to a twelfth embodiment before the resin multilayer substrate 112 is bent, and the lower part of FIG. 19 provides a sectional view of the resin multilayer substrate 112 according to the twelfth embodiment after the resin multilayer substrate 112 has been bent;

FIG. 20 is a sectional view of a resin multilayer substrate 113 according to a thirteenth embodiment;

FIG. 21 is a sectional view of a resin multilayer substrate 114 and an electronic device 414 according to a fourteenth embodiment;

The upper part of FIG. 22 illustrates the location and motion direction of a cutter used to measure the adhesion strength between the first resin member R1 and the resin multilayer body 10, both of which are formed in the resin multilayer substrate, and the lower part of FIG. 22 provides an enlarged view illustrating detailed motions of the cutter;

The left part of FIG. 23 illustrates the cutting location in the resin multilayer substrate, and the right part of FIG. 23 illustrates the resin multilayer substrate after the resin multilayer substrate has been cut along the dashed line indicating the cutting location; and

The upper part of FIG. 24 provides a sectional view of the first resin member R1 during Young's modulus measurement, and the lower part of FIG. 24 provides a sectional view of the second resin member R2 during Young's modulus measurement.

### DESCRIPTION OF THE PREFERRED EMBODIMENTS

Hereafter, preferred embodiments of the present disclosure are described, with specific examples provided in reference to the accompanying drawings. The same reference numerals are assigned to identical elements across different drawings. With consideration for describing key points or ease of understanding, an embodiment for implementing the disclosure is divided into multiple embodiments for explanatory convenience. However, partial omission, replacement, or combination of the configurational features described in different embodiments is permissible. In the second and subsequent embodiments, descriptions of the features common to the first embodiment will not be repeated, and only different features will be described. In particular, the same effects and advantages achieved by the same configurational features will not be described in every embodiment.

### First Embodiment

In a first embodiment, a resin multilayer substrate with patch antennas is described as an example.

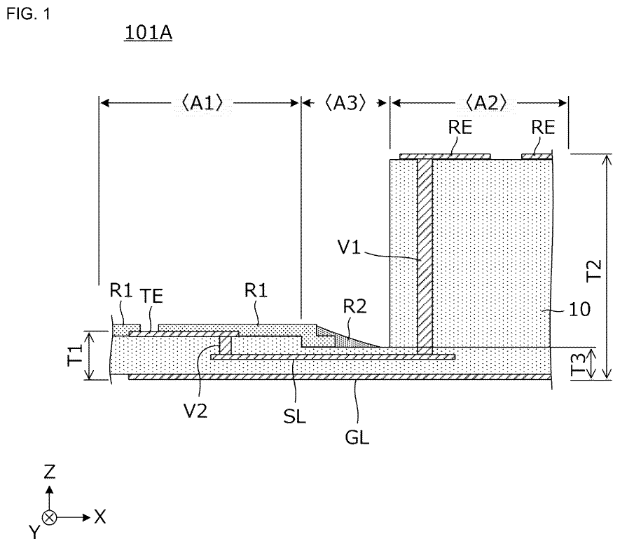

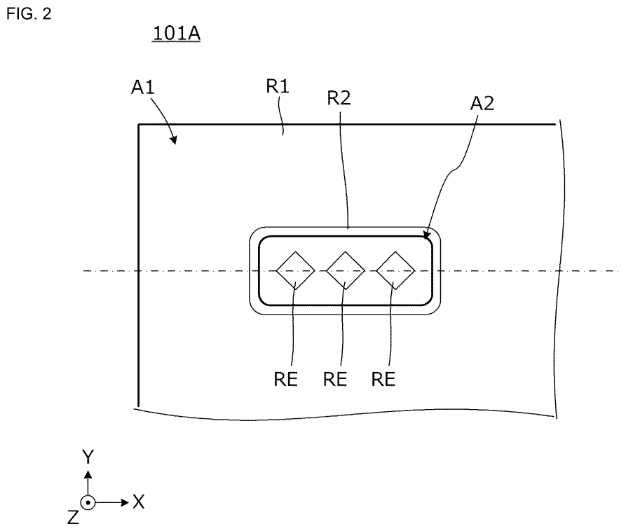

FIG. 1 is a sectional view of a resin multilayer substrate 101A according to the first embodiment. FIG. 2 is a partial plan view of the resin multilayer substrate 101A according to the first embodiment. In sectional views, lines that appear in the section (appear by cutting) are illustrated, and lines located behind the section are not illustrated. The same applies to subsequent embodiments. A single resin multilayer substrate is illustrated in FIGS. 1 and 2. During certain stages of the process of manufacturing such a single resin multilayer, multiple resin multilayer substrates are formed as a continuous object. These multiple resin multilayer substrates are subsequently individualized by cutting the continuous object during the final stage or the stage immediately preceding the final stage of the manufacturing process. The same relationship between the continuous object and individualization applies to the other drawings.

The resin multilayer substrate 101A includes a resin multilayer body 10 composed of a stack of multiple resin layers, some of which include conductor patterns. The resin multilayer body 10 has a first region A1, a second region A2, and a third region A3 positioned between the first region A1 and the second region A2, as layer-direction regions.

In FIG. 1, the interfaces between adjacent resin layers in the layer direction of the multiple resin layers are not illustrated. These interfaces are not illustrated in the subsequent embodiments.

Assuming the average thickness of the first region A1 of the resin multilayer body 10 is expressed as T1, the average thickness of the second region A2 of the resin multilayer body 10 as T2, and the average thickness of the third region A3 of the resin multilayer body 10 as T3, these thicknesses satisfy the relationship T3<T1<T2.

As a result, a step is formed at the boundary between the first region A1 and the third region A3, and a step is formed at the boundary between the second region A2 and the third region A3.

A first resin member (protective film) R1 is affixed to the resin multilayer body 10, extending from the surface of the first region A1 to the third region A3. This first resin member R1 protects and electrically insulates the conductor patterns exposed at the outside layer of the resin multilayer body 10.

A second resin member (reinforcement member) R2 is formed by being applied in the third region A3. As a result, the second resin member R2 covers a portion of the first resin member R1 (does not cover the entire surface). The second resin member R2 covers the first resin member R1, from the end portion of the first resin member R1 affixed in the third region A3 to the boundary portion between the third region A3 and the second region A2. The second resin member R2 covers at least the end portion of the first resin member R1 affixed in the third region A3.

Examples of materials for each member are provided as follows.

### First Resin Member R1

A sheet-type insulating material consisting of an adhesive layer affixed to a polyimide base material. The polyimide base material and the adhesive layer can have any thickness and can be of any color.
A Young's modulus E1 of the first resin member R1 is greater than or equal to 3 GPa and less than 5 Gpa.

### Second Resin Member R2

An epoxy or acrylic resin-based material for underfill or sidefill applications of any color.
A Young's modulus E2 of the second resin member R2 is greater than or equal to 5 Gpa, for example, 7 GPa.

### Resin Multilayer Body 10

A liquid crystal polymer resin or polyimide.

Assuming the Young's modulus of the first resin member R1 is expressed as E1 and the Young's modulus of the second resin member R2 by E2, E1<E2.

The method for measuring the Young's modulus will be described in detail after the embodiments have been described.

Examples of the adhesion strength relationship of the individual members are provided as follows.

Adhesion strength AD1 between the first resin member R1 and the resin multilayer body 10: 0.5 to 2.0 N/mm

Adhesion strength AD2 between the second resin member R2 and the resin multilayer body 10: 1.0 to 3.0 N/mm

Adhesion strength AD12 between the second resin member R2 and the first resin member R1: 0.5 to 2.0 N/mm

The method for measuring the adhesion strengths will be described in detail after the embodiments have been described.

Assuming the adhesion strength between the first resin member R1 and the resin multilayer body 10 is expressed as AD1, and the adhesion strength between the second resin member R2 and the resin multilayer body 10 as AD2, it is preferable that AD2≥AD1.

Radiation electrodes RE are formed on the upper surface of the second region A2 of the resin multilayer body 10. A terminal electrode TE is exposed at the upper surface of the first region A1 of the resin multilayer body 10. A ground conductor layer GL is formed on the lower surface of the resin multilayer body 10.

A signal-line conductor pattern SL, used as a signal line, is formed inside the resin multilayer body 10. This signal-line conductor pattern SL is a conductor pattern formed in one of the multiple resin layers.

Interlayer connection conductors V1 and V2 are formed inside the resin multilayer body 10. The interlayer connection conductor V1 extends in the stacking direction of the resin layers in the resin multilayer body 10 and electrically connects one end portion of the signal-line conductor pattern SL and the radiation electrode RE. The interlayer connection conductor V2 extends in the stacking direction and electrically connects the other end portion of the signal-line conductor pattern SL and the terminal electrode TE.

A microstrip line is constituted by the signal-line conductor pattern SL, the ground conductor layer GL, and a resin layer between the signal-line conductor pattern SL and the ground conductor layer GL. This means that the terminal electrode TE and the radiation electrode RE are connected at high frequencies through the microstrip line.

The radiation electrodes RE, the ground conductor layer GL, and the resin multilayer body 10 constitute a patch antenna.

Various conductor patterns including the signal-line conductor pattern SL, the ground conductor layer GL, the conductor pattern partially serving as the terminal electrode TE, the interlayer connection conductors V1 and V2, and the radiation electrode RE are conductors primarily composed of a material such as Cu or Ag.

In the manufacturing process of the resin multilayer substrate 101A, the first resin member R1 is affixed to the resin multilayer body 10, and the first resin member R1 is adhered to the resin multilayer body 10 through vacuum pressing. Subsequently, the affixing material of the first resin member R1 is cured through oven curing. Next, the second resin member R2 is applied and cured.

In the example illustrated in FIG. 2, multiple radiation electrodes RE are arranged in an array, forming multiple patch antennas that constitute an array antenna. The directivity of the antenna is determined by controlling or setting the phases of the transmit signal emitted from each radiation electrode RE or the receive signal received by each radiation electrode RE. In FIG. 2, the terminal electrode TE illustrated in FIG. 1 is not illustrated.

In the example illustrated in FIG. 1, the first region A1, the second region A2, and the third region A3 coexist. However, the resin multilayer body 10 may be formed by mounting a substrate that constitutes the second region A2 on a multilayer substrate that has the first region and the third region. The same applies to other embodiments.

According to the present embodiment, the thickness T3 of the third region A3 between the first region A1 and the second region A2 is smaller than the thickness T1 of the first region A1 and the thickness T2 of the second region A2. As a result, the third region A3 functions as a depressed portion. The third region A3 thus accommodates the application of a certain amount of the second resin member R2. Consequently, a resin material with low viscosity, such as 40 Pa's or less, can be selected for the second resin member R2. Forming the second resin member R2 from a low-viscosity resin material and applying the second resin member R2 to the end portion of the first resin member R1 effectively reduces the likelihood of the end portion of the first resin member R1 peeling off.

According to the present embodiment, as described above, the end portion of the first resin member R1, which is affixed from the first region A1 to the third region A3, is covered in the third region by the second resin member R2, and AD2≥AD1. As a result, the likelihood of the first resin member R1 peeling off from the resin multilayer body 10 can be reduced, regardless of the relatively weak adhesion strength of the first resin member R1 to the resin multilayer body 10.

In FIG. 1, the thickness T1 of the first region A1 of the resin multilayer body 10 is smaller than the thickness T2 of the second region A2. For this reason, the X-Y plane of the first region A1 can be easily bent around an axis parallel to the Y-axis relative to the second region A2. Assuming such bending stress is intentionally applied, the first resin member R1 can be easily deformed due to the bending stress in the first region A1, owing to the relationship E1<E2 as described above. Thus, the first resin member R1 easily conforms to the deformation of the first region A1. As a result, assuming the bending stress of the first region A1 and the third region A3 is applied to the second region A2, the displacement of the first resin member R1 relative to the surface of the resin multilayer body 10 is suppressed. This also effectively reduces the likelihood of the first resin member R1 peeling off. In other words, the bending resistance of the first region A1 and the third region A3 relative to the second region A2 can be improved assuming the first region A1 and the third region A3 are bent.

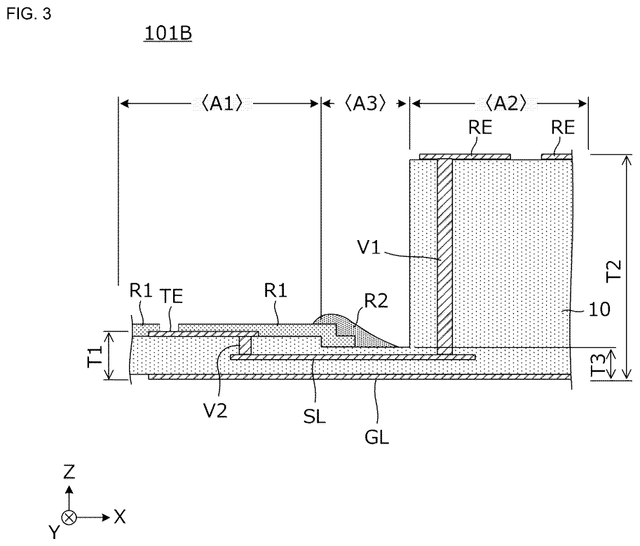

FIG. 3 is a sectional view of a resin multilayer substrate 101B according to the first embodiment. The coverage area of the second resin member R2 differs between this resin multilayer substrate 101B and the resin multilayer substrate 101A illustrated in FIG. 1.

In the resin multilayer substrate 101B illustrated in FIG. 3, the second resin member R2 covers the first resin member R1 from the end portion of the first resin member R1 to the first region A1. Specifically, the second resin member R2 extends to a location where the second resin member R2 spreads over the first region A1 of the resin multilayer body 10. Other structural features are as illustrated in FIG. 1.

Near the boundary between the first region A1 and the third region A3 of the resin multilayer body 10, the adhesion of the first resin member R1 to the resin multilayer body 10 can be relatively low in some cases. In the configuration illustrated in FIG. 3, the second resin member R2 is positioned at the boundary between the first region A1 and the third region A3 of the resin multilayer body 10, thereby reducing the likelihood of the first resin member R1 peeling off from the resin multilayer body 10 at that location. Furthermore, the bonding area between the first resin member R1 and the second resin member R2 is relatively large, which also effectively reduces the likelihood of the first resin member R1 peeling off from the resin multilayer body 10.

### Second Embodiment

In a second embodiment, an example is described in which a region other than the third region exists between the first region and the second region of the resin multilayer body.

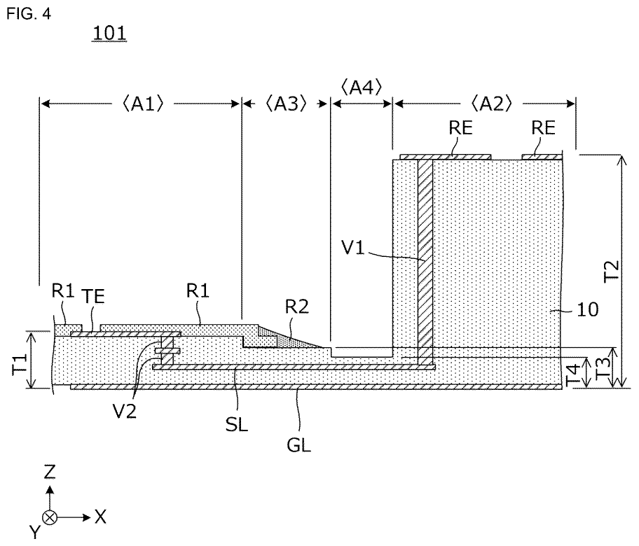

FIG. 4 is a sectional view of a resin multilayer substrate 102 according to the second embodiment. The resin multilayer substrate 102 includes a resin multilayer body 10 composed of a stack of multiple resin layers, some of which include conductor patterns. The resin multilayer body 10 has a first region A1, a second region A2, and a third region A3 positioned between the first region A1 and the second region A2, as layer-direction regions. The resin multilayer body 10 also has a fourth region A4 between the first region A1 and the second region A2.

Assuming the average thickness of the first region A1 of the resin multilayer body 10 is expressed as T1, the average thickness of the second region A2 of the resin multilayer body 10 as T2, the average thickness of the third region A3 of the resin multilayer body 10 as T3, and the average thickness of the fourth region A4 of the resin multilayer body 10 as T4, these thicknesses satisfy the relationship T4<T3<T1<T2.

In the example illustrated in FIG. 4, the first resin member (protective film) R1 is affixed to the resin multilayer body 10 from the third region A3 to the first region A1. The second resin member R2 covers the end portion of the first resin member R1 positioned in the third region A3.

Other structural features are as described in the first embodiment. In the second embodiment, assuming regions other than the third region exist within the resin multilayer body 10 and have different thicknesses, the application area of the second resin member R2 can be reduced, thereby lowering costs. In addition to this, the second embodiment achieves the same effects and advantages as in the first embodiment.

### Third Embodiment

In a third embodiment, an example is described in which the third region of the resin multilayer body is a region that has multiple different thickness levels of the resin multilayer body. In the example of the third embodiment, the structures of the first resin member R1 and the second resin member R2 are different from the second embodiment.

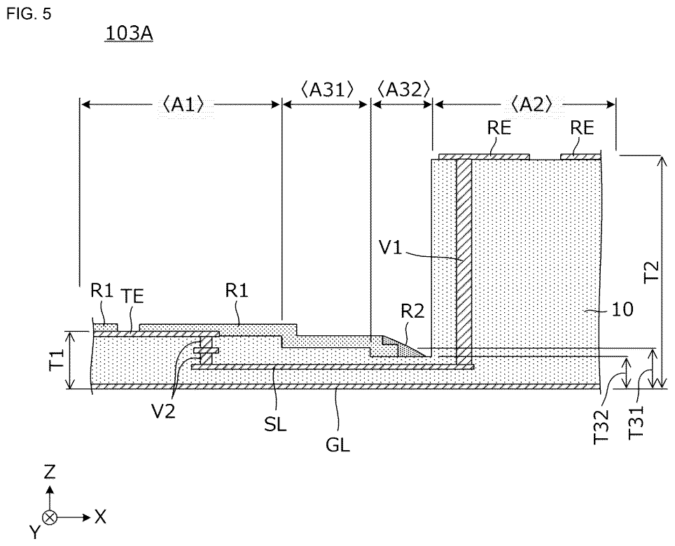

FIG. 5 is a sectional view of a resin multilayer substrate 103A according to the third embodiment. The resin multilayer substrate 103A includes a resin multilayer body 10 composed of a stack of multiple resin layers, some of which include conductor patterns.

The resin multilayer body 10 has a first region A1, a second region A2, and third regions A31 and A32 positioned between the first region A1 and the second region A2, as layer-direction regions.

Assuming the average thickness of the first region A1 of the resin multilayer body 10 is expressed as T1, the average thickness of the second region A2 of the resin multilayer body 10 as T2, the average thickness of the third region A31 of the resin multilayer body 10 as T31, and the average thickness of the other third region A32 of the resin multilayer body 10 as T32, these thicknesses satisfy the relationship T32<T31<T1<T2. According to this, the third regions A31 and A32 have multiple different thickness levels of the resin multilayer body 10.

In the example illustrated in FIG. 5, the first resin member (protective film) R1 is affixed to the resin multilayer body 10 from the third region A32 to the first region A1. The second resin member R2 covers the end portion of the first resin member R1 positioned in the third region A32.

Other structural features are as described in the first and second embodiments. In the example illustrated in FIG. 5, the application area of the second resin member R2 can be reduced, thereby lowering costs. The resin multilayer substrate 103A illustrated in FIG. 5 also achieves the same effects and advantages as in the first and second embodiments.

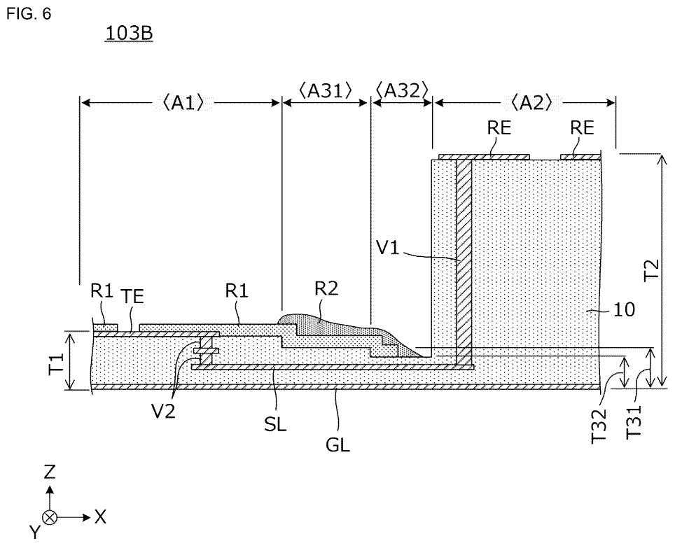

FIG. 6 is a sectional view of a resin multilayer substrate 103B according to the third embodiment. The coverage area of the second resin member R2 differs between this resin multilayer substrate 103B and the resin multilayer substrate 103A illustrated in FIG. 5.

In the resin multilayer substrate 103B illustrated in FIG. 6, the second resin member R2 covers the first resin member R1 from the third region A32 to the first region A1. Specifically, the second resin member R2 extends to a location where the second resin member R2 spreads over the first region A1 of the resin multilayer body 10. Other structural features are as illustrated in FIG. 6.

The resin multilayer substrate may have a structure in which the second resin member R2 covers the first resin member R1 from the third region A32 to the third region A31.

This means that in the third embodiment, the second resin member R2 is affixed to the first resin member R1 from the end portion of the first resin member R1 positioned at a specific level in the third region A31 or A32 to an upper portion one or more levels above the specific level in the third region or affixed from the end portion of the first resin member R1 to the first region A1. Other structural features are as described in the first and second embodiments. The third embodiment also achieves the same effects and advantages as in the first and second embodiments.

### Fourth Embodiment

In a fourth embodiment, a resin multilayer substrate in which the second resin member R2 covers a side surface portion of the second region A2 is described as an example.

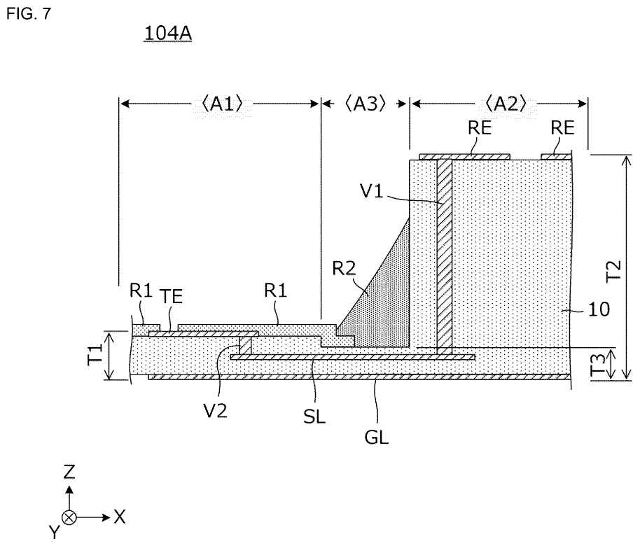

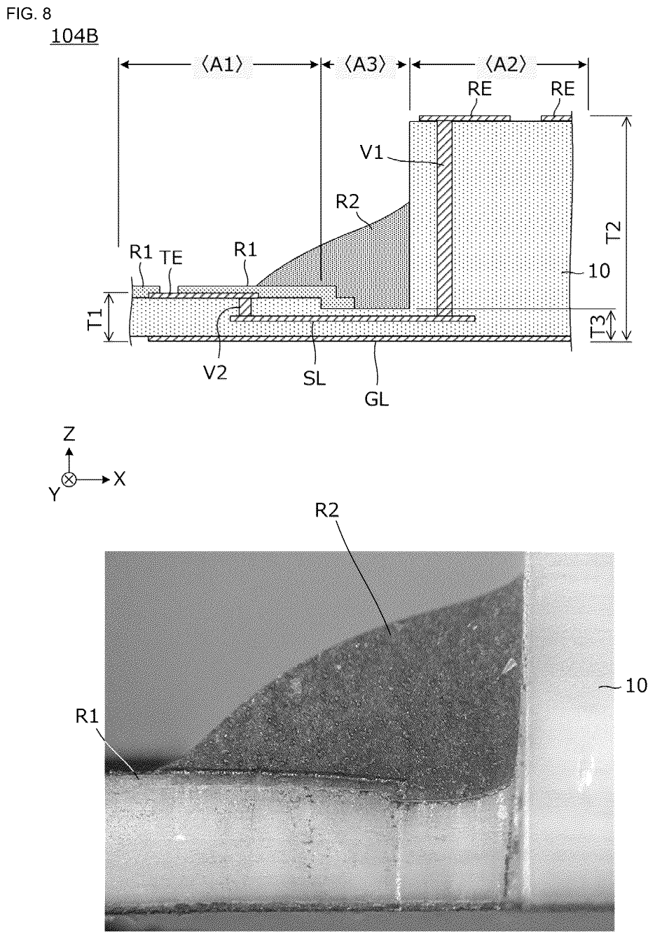

FIG. 7 is a sectional view of a resin multilayer substrate 104A according to the fourth embodiment. The upper part of FIG. 8 provides a sectional view of a resin multilayer substrate 104B according to the fourth embodiment. The lower part of FIG. 8 provides a photograph of the region surrounding the second resin member R2. The structure of the resin multilayer body 10 is the same as the resin multilayer body 10 illustrated in FIGS. 1 and 3 in the first embodiment.

In the example illustrated in FIGS. 7 and 8, the first resin member R1 is affixed to the resin multilayer body 10 from the third region A3 to the first region A1. In the example illustrated in FIG. 7, by covering the third region, the second resin member R2 covers the end portion of the first resin member R1 and also covers the side surface portion of the second region A2. In the example illustrated in FIG. 8, the second resin member R2 covers the first resin member R1 in the first region and the third region and also covers the side surface portion of the second region A2. In both cases, the second resin member R2 covers the side surface portion of the second region A2, extending to a location exceeding the thickness of the first region A1.

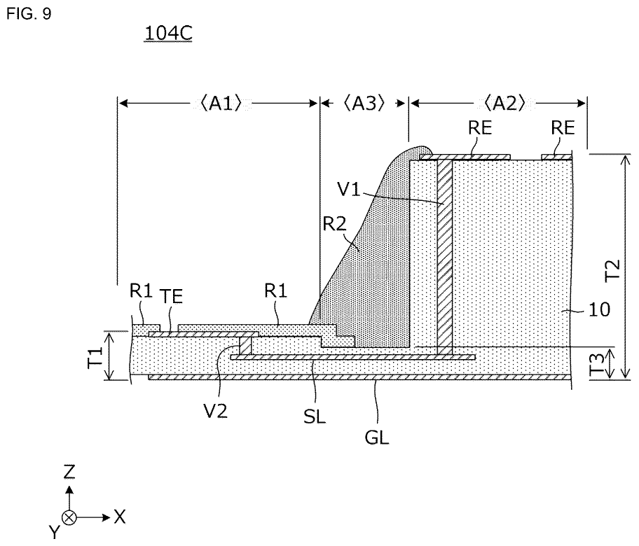

FIG. 9 is a sectional view of a resin multilayer substrate 104C according to the fourth embodiment. The structure of the resin multilayer body 10 is the same as the resin multilayer body 10 illustrated in FIGS. 1 and 3 in the first embodiment.

In the example illustrated in FIG. 9, the first resin member R1 is affixed to the resin multilayer body 10 from the third region A3 to the first region A1. In the example illustrated in FIG. 9, the second resin member R2 is provided from the first region A1 to the second region A2. This indicates that the second resin member R2 covers a portion of the upper surface of the second region A2 as well as the entire side surface of the second region A2. In the example illustrated in FIG. 9, the second resin member R2 also covers the end portion of the radiation electrode RE. This structure also achieves the effect of reducing the likelihood of the Cu foil on the upper surface of the second region A2 peeling off.

In all the resin multilayer substrates 104A, 104B, and 104C, the roughness of the side surface portion of the second region A2 of the resin multilayer body 10 is greater than the roughness of the upper surface of the third region A3.

According to the present embodiment, the second region A2 of the resin multilayer body 10 is fixed by the second resin member R2, resulting in increased bending stability of the second region A2. Additionally, the bending resistance of the base portion of the second region A2 is increased. As a result, the deformation of the second region A2 is suppressed, thereby, for example, reducing changes in antenna characteristics.

Furthermore, as described above, the roughness of the side surface portion of the second region A2 is greater than the roughness of the upper surface of the third region A3. Consequently, the adhesion strength between the second resin member R2 and the side surface of the second region A2 is greater than the adhesion strength between the second resin member R2 and the upper surface of the third region A3. Assuming the first region A1 of the resin multilayer body 10 is bent, stress is applied to the bonding surface between the second region A2 and the second resin member R2. However, because the adhesion strength between the second resin member R2 and the side surface of the second region A2 is relatively high as described above, the likelihood of the second resin member R2 peeling off is reduced assuming the stress is applied.

### Fifth Embodiment

In a fifth embodiment, a resin multilayer substrate is described that differs from the example described in the fourth embodiment with respect to the structure of the side surface and the base portion of the second region A2.

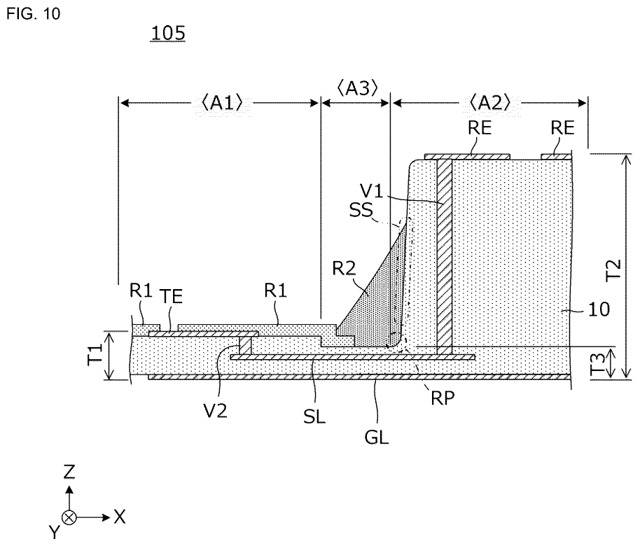

FIG. 10 is a sectional view of a resin multilayer substrate 105 according to the fifth embodiment. The resin multilayer substrate 105 includes a resin multilayer body 10 composed of a stack of multiple resin layers, some of which include conductor patterns. The resin multilayer body 10 has a first region A1, a second region A2, and a third region A3 positioned between the first region A1 and the second region A2, as layer-direction regions.

A side surface SS of the second region A2 tapers upward. The base portion RP of the second region A2 has a curved shape. Other structural features are the same as the resin multilayer substrate 104A illustrated in FIG. 7.

According to the present embodiment, assuming the resin multilayer body 10 is formed by mounting the rigid substrate forming the second region A2 on the flexible multilayer substrate having the first region A1 and third region A3, the bonding strength of the second region A2 to the first region A1 and the third region A3 is increased. In other words, the high adhesion between the second region A2 and the second resin member R2 at the tapered portion suppresses the detachment of the second region A2 from the first region A1 and the third region A3.

Additionally, because the base portion RP of the second region A2 has a curved shape, assuming folding stress is applied to the third region A3, the stress applied to the base portion RP of the second region A2 is relatively small. As a result, the occurrence of cracks at the base portion of the second region A2 is suppressed.

### Sixth Embodiment

In a sixth embodiment, a resin multilayer substrate is described in which a third region includes multiple different thickness levels of the resin multilayer body, and the second resin member R2 covers the side surface portion of the second region A2.

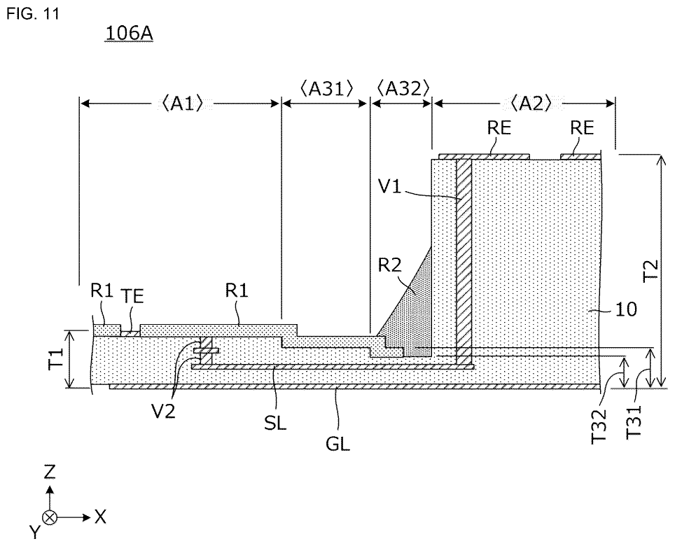

FIG. 11 is a sectional view of a resin multilayer substrate 106A according to the sixth embodiment. The resin multilayer substrate 106A includes a resin multilayer body 10 composed of a stack of multiple resin layers, some of which include conductor patterns. The resin multilayer body 10 has a first region A1, a second region A2, and third regions A31 and A32 positioned between the first region A1 and the second region A2, as layer-direction regions.

Assuming the average thickness of the first region A1 of the resin multilayer body 10 is expressed as T1, the average thickness of the second region A2 of the resin multilayer body 10 as T2, the average thickness of the third region A31 of the resin multilayer body 10 as T31, and the average thickness of the other third region A32 of the resin multilayer body 10 as T32, these thicknesses satisfy the relationship T32<T31<T1<T2. According to this, the third regions A31 and A32 have multiple different thickness levels of the resin multilayer body 10.

In the example illustrated in FIG. 11, the first resin member (protective film) R1 is affixed from the third region A32 to the first region A1 of the resin multilayer body 10. The second resin member R2 covers the part from the end portion of the first resin member R1, positioned in the third region A32, to the side surface portion of the second region A2.

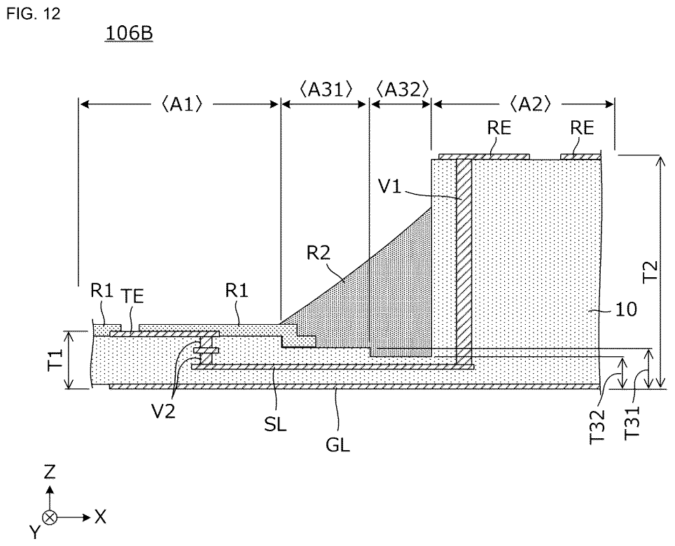

FIG. 12 is a sectional view of a resin multilayer substrate 106B according to the sixth embodiment. The structure of the resin multilayer body 10 is the same as illustrated in FIG. 11. In the example illustrated in FIG. 12, the first resin member (protective film) R1 is affixed from the third region A31 to the first region A1 of the resin multilayer body 10. The second resin member R2 covers the part from the end portion of the first resin member R1, positioned in the third region A31, to the side surface portion of the second region A2.

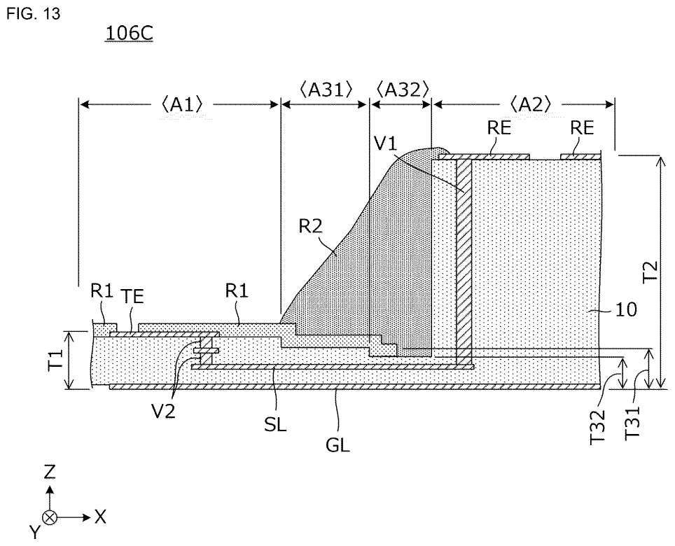

FIG. 13 is a sectional view of a resin multilayer substrate 106C according to the sixth embodiment. The structure of the resin multilayer body 10 is the same as the resin multilayer body 10 illustrated in FIGS. 1 and 3 in the first embodiment.

In the example illustrated in FIG. 13, the first resin member R1 is affixed to the resin multilayer body 10 from the third region A32 to the first region A1. In the example illustrated in FIG. 13, the second resin member R2 is provided from the first region A1 to the second region A2. This indicates that the second resin member R2 covers a portion of the upper surface of the second region A2 as well as the entire side surface of the second region A2. In the example illustrated in FIG. 13, the second resin member R2 also covers the end portion of the radiation electrode RE. This structure also achieves the effect of reducing the likelihood of the Cu foil on the upper surface of the second region A2 peeling off.

According to the present embodiment, the second region A2 is fixed by the second resin member R2, resulting in increased bending stability of the second region A2. Additionally, the bending resistance of the base portion of the second region A2 is increased.

As described above, in the case in which the third region includes multiple different thickness levels of the resin multilayer body 10, assuming the second resin member R2 covers the first resin member R1 and the surface of the resin multilayer body 10 from the end portion of the first resin member R1 to the side surface of the second region A2, the same effects and advantages as the resin multilayer substrate described in the fourth embodiment are achieved.

### Seventh Embodiment

In a seventh embodiment, a resin multilayer substrate is described as an example in which the structure of the upper surface of the second region is different from the examples described above.

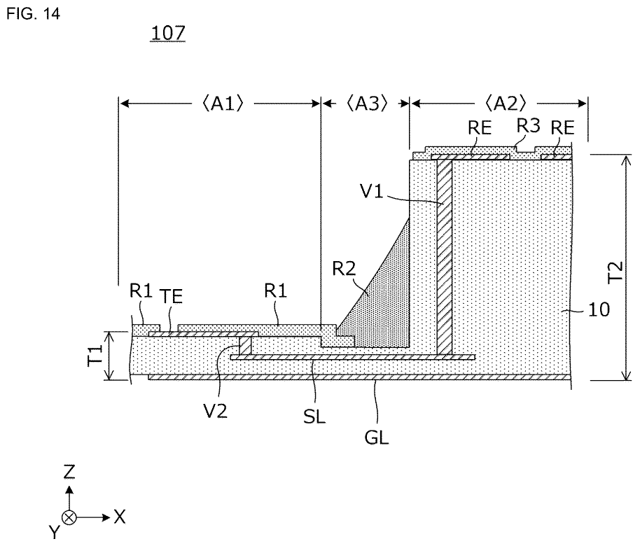

FIG. 14 is a sectional view of a resin multilayer substrate 107 according to the seventh embodiment. The resin multilayer substrate 107 includes a third resin member R3 that covers the upper surface of the second region A2 as well as the upper surface of the radiation electrodes RE formed on the upper surface of the second region A2. The third resin member R3 is not in contact with the second resin member R2. In other words, a portion of the second region of the resin multilayer body 10 is exposed between the third resin member R3 and the second resin member R2. Similar to the first resin member R1, the third resin member R3 is, for example, a sheet-type insulating material consisting of an adhesive layer affixed to a polyimide base material.

Other structural features are the same as the structural features of the resin multilayer substrate 104A illustrated in FIG. 7 in the fourth embodiment.

According to the present embodiment, the third resin member R3 and the second resin member R2 are not continuous. Consequently, the third resin member R3 is not affected by bending of the first region A1 and the third region A3, thereby enhancing the peeling resistance of the third resin member R3.

### Eighth Embodiment

In an eighth embodiment, a resin multilayer substrate in which the third resin member covers a side surface portion of the second region is described as an example.

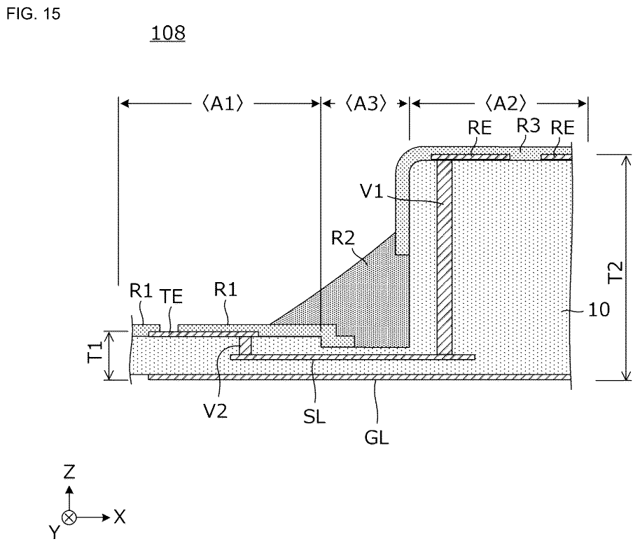

FIG. 15 is a sectional view of a resin multilayer substrate 108 according to the eighth embodiment. In this example, a third resin member R3 is formed from the upper surface to the side surface of the second region A2. The second resin member R2 is formed on the side surface of the second region, extending to a location at which the second resin member R2 covers the end portion of the third resin member R3. A curve is formed from the upper surface to the side surface of the second region A2, thereby facilitating the affixing of the third resin member R3 to the second region A2 of the resin multilayer body 10.

Other structural features are the same as the structural features of the resin multilayer substrate 104A illustrated in FIG. 7 in the fourth embodiment.

According to the present embodiment, the second resin member R2 covers the end portion of the third resin member R3, thereby enhancing the bending resistance of the third resin member R3 with respect to peeling under bending.

### Ninth Embodiment

In a ninth embodiment, the relationship between the conductor patterns in the second region of the resin multilayer body and the second resin member as well as the third resin member, both of which cover the side surface of the second region, is described as an example.

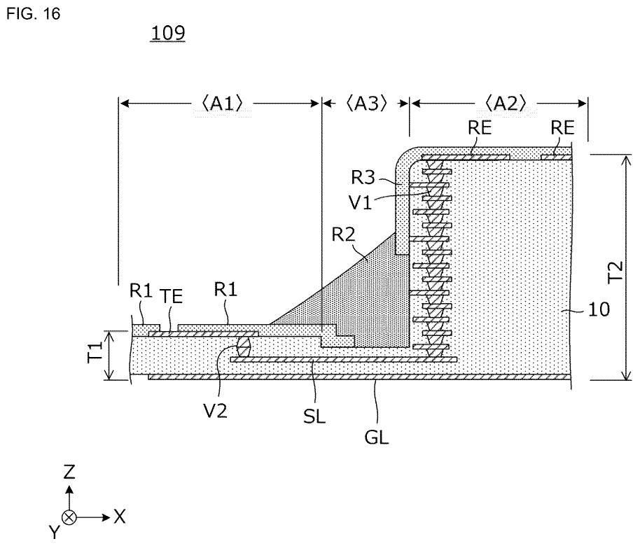

FIG. 16 is a sectional view of a resin multilayer substrate 109 according to the ninth embodiment. Within the second region A2 of the resin multilayer body 10, a stacking-direction conductor path is formed by stacking interlayer connection conductors V1 and resin layers having conductor foils that are in contact with the interlayer connection conductors V1. Some of the end portions of the conductor foils reach the side surface of the second region A2.

The third resin member R3 is affixed to the exposed portions of the conductor foils. The second resin member R2, which covers the side surface of the second region A2, also covers the exposed portions of the conductor foils.

Other structural features are the same as the structural features of the resin multilayer substrate 104A illustrated in FIG. 7 in the fourth embodiment.

According to the present embodiment, improper electrical conduction from the conductor patterns at the side surface of the second region A2 is prevented. In this regard, the size of the second region A2 in the X direction or along the X-Y plane can be reduced.

### Tenth Embodiment

In a tenth embodiment, the relationship between the conductor patterns in the second region of the resin multilayer body and the second resin member, which covers the side surface of the second region, is described as an example.

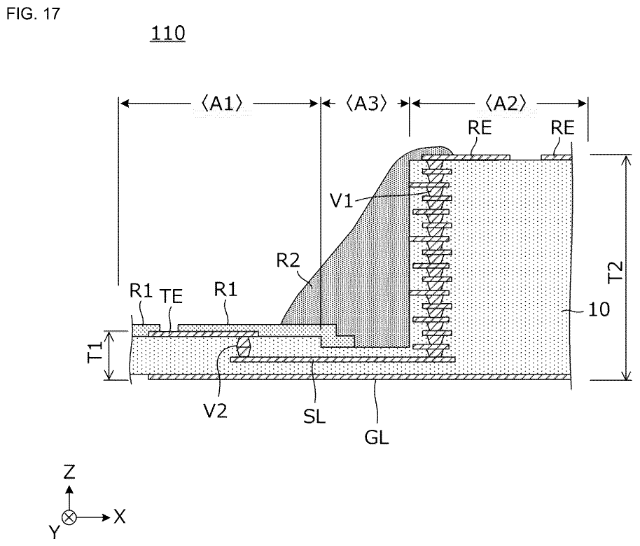

FIG. 17 is a sectional view of a resin multilayer substrate 110 according to the tenth embodiment. Within the second region A2 of the resin multilayer body 10, a stacking-direction conductor path is formed by stacking interlayer connection conductors V1 and resin layers having conductor foils that are in contact with the interlayer connection conductors V1. Some of the end portions of the conductor foils are exposed at the side surface of the second region A2.

The second resin member R2, which covers the side surface of the second region A2, also covers the exposed portions of the conductor foils.

Other structural features are the same as the structural features of the resin multilayer substrate 104A illustrated in FIG. 7 in the fourth embodiment.

According to the present embodiment, improper electrical conduction from the conductor patterns at the side surface of the second region A2 is prevented. In this regard, the size of the second region A2 in the X direction or along the X-Y plane can be reduced.

### Eleventh Embodiment

In an eleventh embodiment, a resin multilayer substrate is described as an example in which both the first resin member and the second resin member are positioned at two different (separated) locations in the stacking direction of the multiple resin layers in the resin multilayer body.

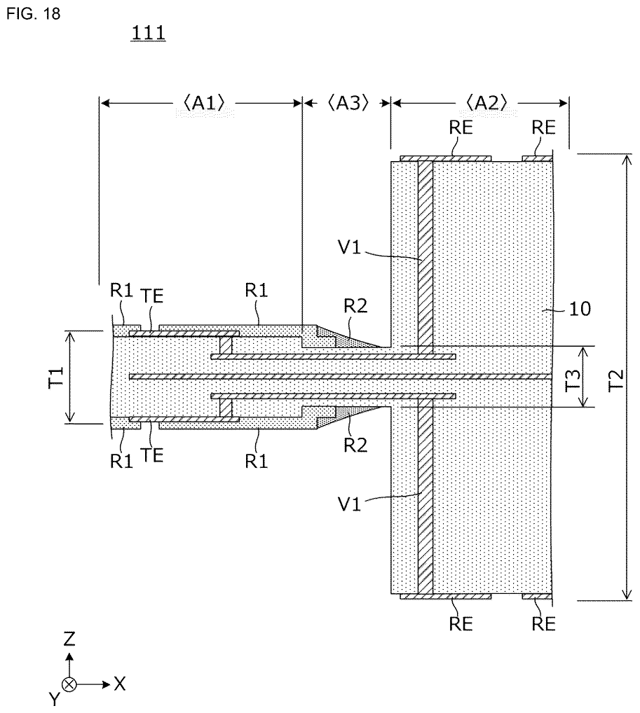

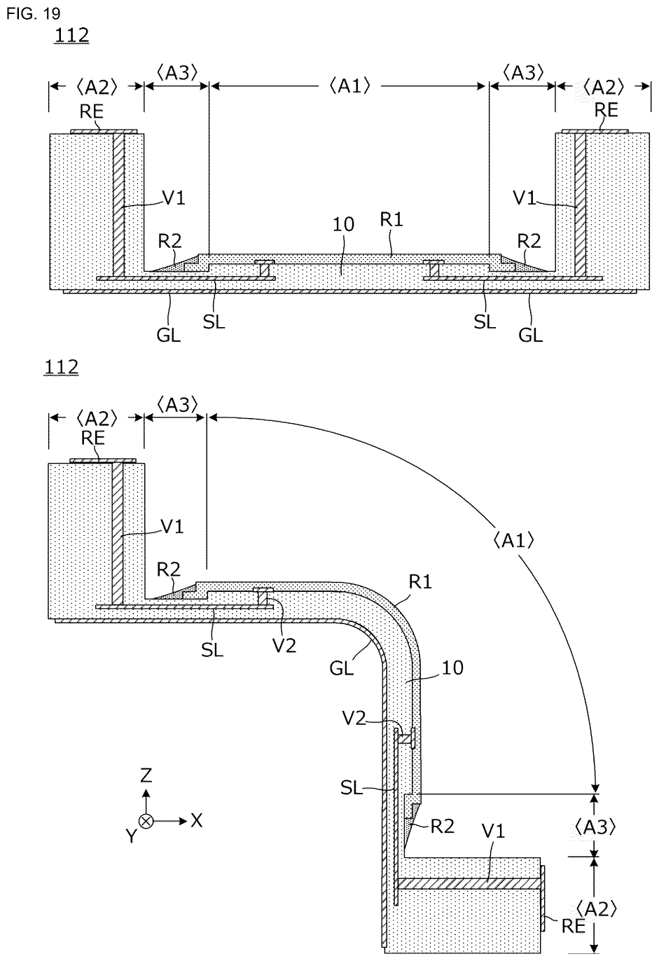

FIG. 18 is a sectional view of a resin multilayer substrate 111 according to the eleventh embodiment. The resin multilayer substrate 111 includes a resin multilayer body 10 composed of a stack of multiple resin layers, some of which include conductor patterns.

The resin multilayer body 10 has a first region A1, a second region A2, and a third region A3, as layer-direction regions of the resin multilayer body 10. Assuming the thickness of the first region A1 of the resin multilayer body 10 is expressed as T1, the thickness of the second region A2 of the resin multilayer body 10 as T2, and the thickness of the third region A3 of the resin multilayer body 10 as T3, these thicknesses satisfy the relationship T3<T1<T2.

A step is formed at the boundary between the first region A1 and the third region A3, and a step is formed at the boundary between the second region A2 and the third region A3.

A first resin member (protective film) R1 is affixed to the resin multilayer body 10, extending from the surface of the first region A1 to the third region A3. A second resin member (reinforcement member) R2 covers the third region A3.

As evident from a comparison with the example illustrated in FIG. 1, the resin multilayer substrate 111 of the eleventh embodiment includes the first resin member R1 and the second resin member R2 at two different (separated) locations in the stacking direction of multiple resin layers in the resin multilayer body 10.

According to the present embodiment, assuming the resin multilayer substrate 111 is accommodated in the casing of an electronic device, the degree of freedom in placement is enhanced; for example, the resin multilayer substrate can be accommodated in a limited space. Furthermore, because the resin multilayer substrate 111 includes radiation electrodes RE oriented in different directions, the resin multilayer substrate 111 can be used as a wide-directional or bi-directional antenna.

Other structural features and the effects and advantages are as described in the first embodiment.

### Twelfth Embodiment

In a twelfth embodiment, a resin multilayer substrate that can be bent in the first region of the resin multilayer body is described as an example.

The upper part of FIG. 19 provides a sectional view of a resin multilayer substrate 112 according to the twelfth embodiment before the resin multilayer substrate 112 is bent (folded). The lower part of FIG. 19 provides a sectional view of the resin multilayer substrate 112 according to the twelfth embodiment after the resin multilayer substrate 112 has been bent.

As illustrated in the upper part of FIG. 19, the resin multilayer substrate 112 includes a resin multilayer body 10 composed of a stack of multiple resin layers, some of which include conductor patterns. The resin multilayer body 10 has a single first region A1, second regions A2, and third regions A3, as layer-direction regions of the resin multilayer body 10. Assuming the thickness of the first region A1 of the resin multilayer body 10 is expressed as T1, the thickness of the second region A2 of the resin multilayer body 10 as T2, and the thickness of the third region A3 of the resin multilayer body 10 as T3, these thicknesses satisfy the relationship T3<T1<T2.

A first resin member (protective film) R1 is affixed to the resin multilayer body 10, extending from the surface of the first region A1 to the third regions A3. Second resin members (reinforcement member) R2 cover the third regions A3.

As evident from a comparison with the example illustrated in FIG. 1, the resin multilayer substrate 112 of the twelfth embodiment includes the first resin member R1 and the second resin members R2 at two different (separated) locations in the layer direction of the resin multilayer body 10.

As illustrated in the lower part of FIG. 19, assuming the resin multilayer substrate 112 is bent by 90° around an axis along the Y-axis at the center of the first region A1, the two radiation electrodes RE are arranged to point in directions that are different from each other by 90°.

According to the present embodiment, assuming the resin multilayer substrate 112 is accommodated in the casing of an electronic device, the degree of freedom in placement is enhanced; for example, the resin multilayer substrate can be accommodated in a limited space. Furthermore, because the resin multilayer substrate 112 includes radiation electrodes RE1 and RE2 oriented in different directions, the resin multilayer substrate 112 can be used as a wide-directional antenna.

### Thirteenth Embodiment

In a thirteenth embodiment, a resin multilayer substrate is described as an example in which the structure of the second region is different from the examples described above.

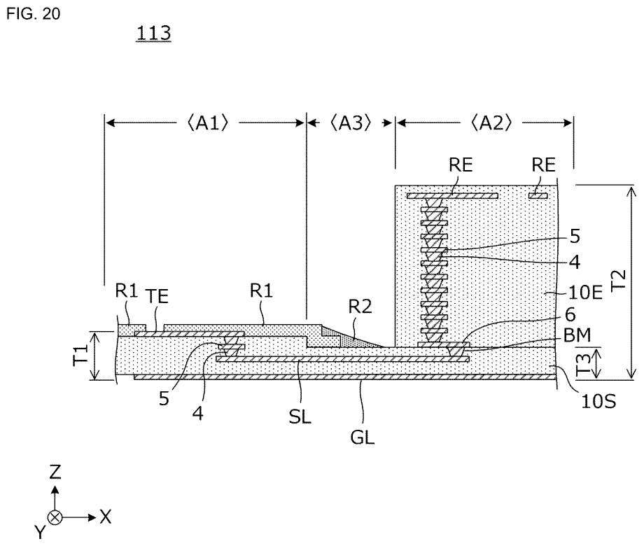

FIG. 20 is a sectional view of a resin multilayer substrate 113 according to the thirteenth embodiment. This resin multilayer substrate 113 includes a substrate section 10S and a mounted section 10E mounted on the substrate section 10S. The second region A2 is constituted by the substrate section 10S and the mounted section 10E. The first region A1 and the third region A3 are formed by the substrate section 10S excluding the mounting region of the substrate section 10S on which the mounted section 10E is mounted.

The substrate section 10S and the mounted section 10E include multiple resin layers, as well as conductor layers and interlayer connection conductors that are affixed to some of the resin layers. The conductor layers and the interlayer connection conductors are conductors primarily composed of a material such as Cu or Ag.

A connection conductor BM is formed by being applied into a cavity in the topmost resin layer of the substrate section 10S. The connection conductor BM is composed of a heat-melt metal such as solder. An end portion of the signal-line conductor pattern SL is positioned in the lower layer under the connection conductor BM.

Radiation electrodes RE are formed in the upper part of the mounted section 10E. A terminal electrode 6 is formed at the mounting surface (lower surface) of the mounted section 10E. The terminal electrode 6 and the radiation electrode RE are electrically connected via the interlayer connection conductors 4 and the conductor layers 5.

The terminal electrode 6 in the mounted section 10E is electrically connected to the one end portion of the signal-line conductor pattern SL formed within the substrate section 10S. A terminal electrode TE and the other end of the signal-line conductor pattern SL are connected in the stacking direction by the conductor layer 5 and the interlayer connection conductor 4.

The resin multilayer body may be formed by the substrate section 10S and the mounted section 10E in this manner. Other structural features are the same as the structural features in the embodiments described above, including the first embodiment.

In the resin multilayer body, the first region A1, the second region A2, and the third region A3 may all be formed from the same type of resin material. Alternatively, the second region A2 may be formed by bonding a substrate of a different type onto the resin substrate that forms the first region A1 and third region A3. In other words, the resin member of the substrate section 10S and the resin member of the mounted section 10E may be composed of different resin materials. However, assuming the resin member of the substrate section 10S and the resin member of the mounted section 10E are composed of the same type of resin material, high bonding strength can be achieved because no interface of different materials is formed. Whether the resin members are composed of the same-type resin material can be verified using a Fourier Transform Infrared (FT-IR) spectrometer. Specifically, assuming the peaks of the spectra measured for the mounted section 10E and the substrate section 10S using a Fourier Transform Infrared (FT-IR) spectrometer are identical, it confirms that the mounted section 10E and the substrate section 10S are composed of the same type of resin material.

Assuming a thermoplastic is used, the same type of resin material exhibits a small difference in melting point. Whether the resin member of the substrate section 10S and the resin member of the mounted section 10E are composed of the same type of resin material can be verified based on the endothermic peak obtained through differential scanning calorimetry (DSC). Specifically, using the Rigaku DSC8230, the temperatures of two resin materials are increased at a rate of 10° C./minute until melting, then lowered, and subsequently increased again at a rate of 10° C./minute. Assuming the difference in melting points of the two resin materials at this stage is 5° C. or less, the two resin materials can be regarded as the same type of resin material.

### Fourteenth Embodiment

In a fourteenth embodiment, an electronic device having a resin multilayer substrate with an electronic component mounted and an additional substrate is described as an example.

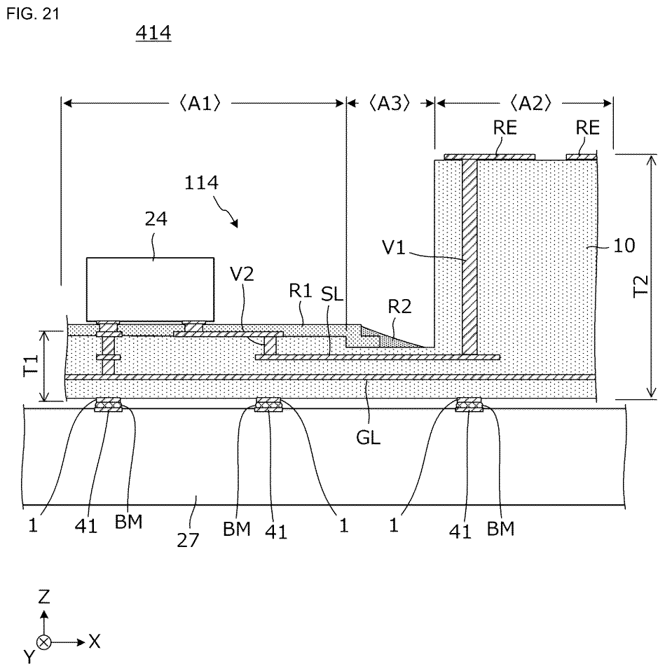

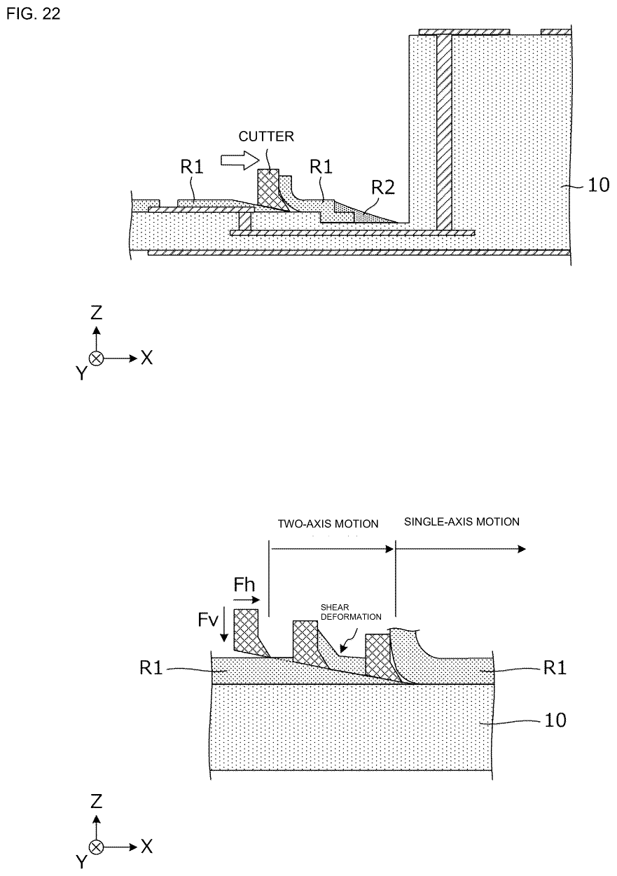

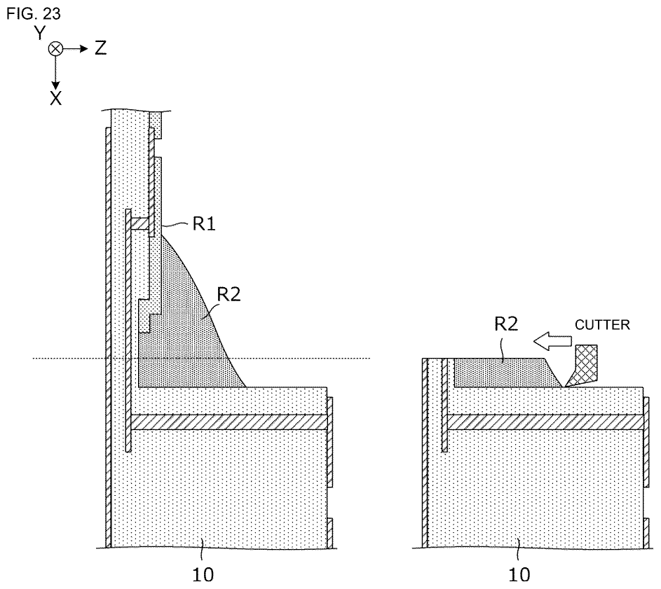

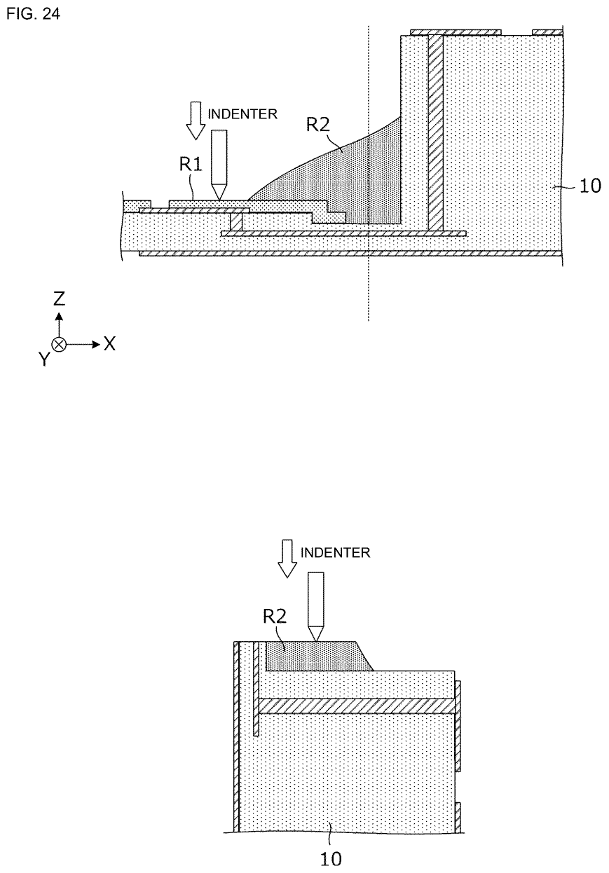

FIG. 21 is a sectional view of a resin multilayer substrate 114 and an electronic device 414 according to the fourteenth embodiment.

An electronic component 24 is mounted in a first region A1 of a resin multilayer body 10. The electronic component 24 is not hatched in the drawing.

The electronic device 414 includes a resin multilayer substrate 114 and an additional substrate 27. The resin multilayer substrate 114 is mounted on the additional substrate 27. The additional substrate 27 is not hatched in the drawing.

The structural features of the resin multilayer substrate 114 are the same as the structural features of the resin multilayer substrate 101A illustrated in FIG. 1 in the first embodiment.

### Fifteenth Embodiment

In a fifteenth embodiment, an electronic device with a casing is described as an example.

The electronic device according to the present embodiment includes the resin multilayer substrate described in any of the first to thirteenth embodiments and a casing that accommodates the resin multilayer substrate.

The casing that accommodates the resin multilayer substrate has a size and shape sufficient to accommodate (enclose) the resin multilayer substrate.

### Method for Measuring Adhesion Strength

As a typical method for measuring adhesion strength, adhesion strength is measured through a tensile test using a tensile strength tester. To measure the adhesion strengths of the members in a resin multilayer substrate after manufacturing, the adhesion strength is determined by measuring the horizontal force, vertical force, and vertical displacement exerted on a sharp cutter assuming the cutter cuts a specific member from its surface to the interface of another member at an extremely slow speed and peel off the specific member. For example, adhesion strength is measured using a device called SAICAS, manufactured by DAIPLA WINTES.

First, the method for measuring an adhesion strength AD1 between the first resin member R1 and the resin multilayer body 10, which are described in the embodiments, is described as an example.

The upper part of FIG. 22 illustrates the location and motion direction of a cutter used to measure the adhesion strength between the first resin member R1 and the resin multilayer body 10, both of which are formed in the resin multilayer substrate. The lower part of FIG. 22 provides an enlarged view illustrating detailed motions of the cutter.

As illustrated in the upper part of FIG. 22, a sharp cutter moves from the surface of the first resin member R1 to the interface of the resin multilayer body 10, cutting the first resin member R1 at an extremely slow speed and peeling off the first resin member R1 from the resin multilayer body 10.

In the drawing illustrated in the lower part of FIG. 22, the cutter is first moved in a two-axis direction by the application of a force Fv in the −Z direction and a force Fh in the +X direction, thereby cutting the first resin member R1 obliquely. Assuming the cutting reaches a certain thickness of the first resin member R1, shear deformation occurs. The first resin member R1 then peels off from the resin multilayer body 10. Subsequently, the cutter is moved in a single-axis direction of the +X direction. The peak of the force Fh in the +X direction applied to the cutter while the cutter is moved in this manner can be considered the adhesion strength between the first resin member R1 and the resin multilayer body 10.

The following provides an example of the method for measuring the adhesion strength AD2 between the second resin member R2 and the resin multilayer body 10.

The left part of FIG. 23 illustrates the cutting location in the resin multilayer substrate. The right part of FIG. 23 illustrates the resin multilayer substrate after the resin multilayer substrate has been cut along the dashed line indicating the cutting location. In this state, the thickness of the second resin member R2 is the same thickness as the first resin member R1 illustrated in FIG. 22.

In the drawing illustrated in the right part of FIG. 23, the cutter is moved in the −Z direction to cut the second resin member R2. Assuming the force applied to the second resin member R2 reaches a certain value, shear deformation occurs within the second resin member R2. The second resin member R2 then peels off from the resin multilayer body 10. The peak of the force in the −Z direction applied to the cutter while the cutter is moved in this manner can be considered the adhesion strength between the second resin member R2 and the resin multilayer body 10. Method for measuring Young's modulus

An example of the method for measuring the Young's modulus of the first resin member R1 is described. As the method for measuring the Young's modulus, a nanoindenter test is conducted in accordance with JIS Z 2255 and ISO 14577 standards. For example, the Young's modulus is determined from load-displacement data using a Micro nanoindenter device manufactured by KLA.

The upper part of FIG. 24 provides a sectional view of the first resin member R1 during Young's modulus measurement. A Vickers or Berkovich triangular pyramidal indenter is used as the indenter. The Young's modulus is measured using this indenter, applied perpendicular to the surface of the first resin member R1, at an indentation depth of approximately 1/10 of the film thickness. For example, assuming the film thickness is 10 μm, the indentation depth is approximately 1 μm.

The lower part of FIG. 24 provides a sectional view of the second resin member R2 during Young's modulus measurement. The illustrated shape represents the resin multilayer substrate cut along the dashed line illustrated at the upper part of FIG. 24. A Vickers or Berkovich triangular pyramidal indenter is used as the indenter. The Young's modulus is measured using this indenter, applied perpendicular to the surface of the second resin member R2, at an indentation depth of approximately 1/10 of the film thickness. For example, assuming the film thickness is 10 μm, the indentation depth is approximately 1 μm.

The foregoing has described various embodiments of the present disclosure. However, these embodiments are merely illustrative and are not intended to limit the scope of present disclosure. Various omissions, substitutions, or modifications may be made to the embodiments according to the present disclosure without departing from the gist of the disclosure. Embodiments obtained through various omissions, substitutions, or modifications are embodied in the scope and gist of the present disclosure and are included in the disclosures described in the claims of the present application and their equivalents.

For example, in the above embodiments, an example is described in which radiation electrodes are formed in the second region A2 of the resin multilayer body 10. However, the electrodes formed in the second region A2 are not limited to radiation electrodes.

In the above embodiments, an example is described in which interlayer connection conductors are formed in the first region A1 and the second region A2. However, these interlayer connection conductors are not necessarily included.

In the above embodiments, microstrip lines or tri-plate strip lines are constructed by forming the signal-line conductor pattern SL and the ground conductor layer GL. However, these transmission lines are not necessarily included.

The resin multilayer substrates and electronic devices of the present disclosure may be provided as the embodiments described below.

<1>

A resin multilayer substrate comprising:
a resin multilayer body composed of a stack of a plurality of resin layers, at least one of the resin layers including a conductor pattern,
the resin multilayer body having a first region, a second region, and a third region between the first region and the second regions as layer-direction regions,

Assuming the average thickness of the first region of the resin multilayer body is expressed as T1, the average thickness of the second region of the resin multilayer body as T2, and the average thickness of the third region of the resin multilayer body as T3, these thicknesses are in the relationship T3<T1<T2,
a first resin member (protective film) covering an area from a surface of the first region to the third region; and
a second resin member (reinforcement member) formed within the third region, wherein
the second resin member covers a portion of the first resin member, covering an end portion of the first resin member positioned in the third region,

Assuming the Young's modulus of the first resin member is expressed as E1 and that of the second resin member as E2, the relationship is E1<E2,
assuming an adhesion strength between the first resin member and the resin multilayer body is expressed as AD1 and an adhesion strength between the second resin member and the resin multilayer body as AD2, AD2≥AD1.
   <2>

The resin multilayer substrate according to <1>, wherein
the second resin member covers the first resin member from the end portion of the first resin member to the first region.
   <3>

The resin multilayer substrate according to <1> or <2>, wherein
the third region has a plurality of different thickness levels of the resin multilayer body, and
the second resin member covers the first resin member from the end portion of the first resin member positioned at a specific level among the thickness levels in the third region to an upper portion one or more levels above the specific level in the third region or from the end portion of the first resin member to the first region.
   <4>

The resin multilayer substrate according to any of <1> to <3>, wherein
the second resin member covers a side surface portion of the second region, extending to a location exceeding a thickness of the first region.
   <5>

The resin multilayer substrate according to <4>, wherein
an adhesion strength between the second resin member and a side surface of the second region is greater than an adhesion strength between the second resin member and an upper surface of the third region.
   <6>

The resin multilayer substrate according to <4> or <5>, wherein
the second resin member covers the conductor pattern, the conductor pattern reaching the side surface portion of the second region.
   <7>

The resin multilayer substrate according to any of <1> to <6>, comprising:
a third resin member covering an upper surface of the second region, wherein
an end portion of the third resin member is not in contact with the second resin member.
   <8>

The resin multilayer substrate according to any of <1> to <6>, comprising:
a third resin member formed on a side surface of the second region, wherein
the second resin member covers an end portion of the third resin member at the side surface of the second region.
   <9>

The resin multilayer substrate according to any of <1> to <6>, comprising:
a third resin member covering an upper surface of the second region, wherein
the second resin member covers an end portion of the third resin member at the upper surface of the second region.
   <10>

An electronic device comprising:
the resin multilayer substrate according to any of <1> to <9>; and
an electronic component mounted at the resin multilayer substrate, or an additional substrate having the resin multilayer substrate.
   <11>

An electronic device comprising:
the resin multilayer substrate according to any of <1> to <9>; and
a casing enclosing the resin multilayer substrate.

What is claimed is:

1. A resin multilayer substrate comprising:
a resin multilayer body composed of a stack of a plurality of resin layers, at least one of the resin layers including a conductor pattern,
the resin multilayer body having a first region, a second region, and a third region between the first region and the second regions as layer-direction regions,
assuming an average thickness of the first region of the resin multilayer body is expressed as T1, an average thickness of the second region of the resin multilayer body as T2, and an average thickness of the third region of the resin multilayer body as T3, T3<T1<T2;
a first resin member covering an area from a surface of the first region to the third region; and
a second resin member formed within the third region, wherein
the second resin member covers a portion of the first resin member, covering an end portion of the first resin member positioned in the third region,
assuming a Young's modulus of the first resin member is expressed as E1 and a Young's modulus of the second resin member as E2, E1<E2,
assuming an adhesion strength between the first resin member and the resin multilayer body is expressed as AD1 and an adhesion strength between the second resin member and the resin multilayer body as AD2, AD2≥AD1.

2. The resin multilayer substrate according to claim 1, wherein
the second resin member covers the first resin member from the end portion of the first resin member to the first region.

3. The resin multilayer substrate according to claim 2, wherein
the third region has a plurality of different thickness levels of the resin multilayer body, and
the second resin member covers the first resin member from the end portion of the first resin member positioned at a specific level among the thickness levels in the third region to an upper portion one or more levels above the specific level in the third region or from the end portion of the first resin member to the first region.

4. The resin multilayer substrate according to claim 2, wherein
the second resin member covers a side surface portion of the second region, extending to a location exceeding a thickness of the first region.

5. The resin multilayer substrate according to claim 4, wherein
an adhesion strength between the second resin member and a side surface of the second region is greater than an adhesion strength between the second resin member and an upper surface of the third region.

6. The resin multilayer substrate according to claim 4, wherein
the second resin member covers the conductor pattern, the conductor pattern reaching the side surface portion of the second region.

7. The resin multilayer substrate according to claim 2, comprising:
a third resin member covering an upper surface of the second region, wherein
an end portion of the third resin member is not in contact with the second resin member.

8. The resin multilayer substrate according to claim 2, comprising:
a third resin member formed on a side surface of the second region, wherein
the second resin member covers an end portion of the third resin member at the side surface of the second region.

9. The resin multilayer substrate according to claim 2, comprising:
a third resin member covering an upper surface of the second region, wherein
the second resin member covers an end portion of the third resin member at the upper surface of the second region.

10. An electronic device comprising:
the resin multilayer substrate according to claim 2; and
an electronic component mounted at the resin multilayer substrate, or an additional substrate having the resin multilayer substrate.

11. An electronic device comprising:
the resin multilayer substrate according to claim 2; and
a casing enclosing the resin multilayer substrate.

12. The resin multilayer substrate according to claim 1, wherein
the third region has a plurality of different thickness levels of the resin multilayer body, and
the second resin member covers the first resin member from the end portion of the first resin member positioned at a specific level among the thickness levels in the third region to an upper portion one or more levels above the specific level in the third region or from the end portion of the first resin member to the first region.

13. The resin multilayer substrate according to claim 1, wherein
the second resin member covers a side surface portion of the second region, extending to a location exceeding a thickness of the first region.

14. The resin multilayer substrate according to claim 13, wherein
an adhesion strength between the second resin member and a side surface of the second region is greater than an adhesion strength between the second resin member and an upper surface of the third region.

15. The resin multilayer substrate according to claim 13, wherein
the second resin member covers the conductor pattern, the conductor pattern reaching the side surface portion of the second region.

16. The resin multilayer substrate according to claim 1, comprising:
a third resin member covering an upper surface of the second region, wherein
an end portion of the third resin member is not in contact with the second resin member.

17. The resin multilayer substrate according to claim 1, comprising:
a third resin member formed on a side surface of the second region, wherein
the second resin member covers an end portion of the third resin member at the side surface of the second region.

18. The resin multilayer substrate according to claim 1, comprising:
a third resin member covering an upper surface of the second region, wherein
the second resin member covers an end portion of the third resin member at the upper surface of the second region.

19. An electronic device comprising:
the resin multilayer substrate according to claim 1; and
an electronic component mounted at the resin multilayer substrate, or an additional substrate having the resin multilayer substrate.

20. An electronic device comprising:
the resin multilayer substrate according to claim 1; and
a casing enclosing the resin multilayer substrate.
